(19) United States
(12) Patent Application Publication
(10) Pub. No.: US 2015/0148111 A1
(43) Pub. Date: May 28, 2015

(54) CLOSURE APPARATUS OF WIRELESS COMMUNICATION DEVICE

(71) Applicant: KMW Inc., Hwaseong (KR)

(72) Inventors: Duk Yong Kim, Yongin (KR); Chang-Woo Yoo, Suwon (KR); Chi-Back Ryu, Hwaseong (KR); Min-Sik Park, Suwon (KR)

(73) Assignee: KMW Inc.

(21) Appl. No.: 14/614,890

(22) Filed: Feb. 5, 2015

Related U.S. Application Data
(63) Continuation of application No. PCT/KR2012/006248, filed on Aug. 6, 2012.

(51) Int. Cl. H05K 7/20; H04M 1/11; H05K 5/02

(52) U.S. Cl. CPC H05K 7/20; H05K 5/02; H04M 1/11
USPC 455/575.8

(57) ABSTRACT

The present invention is a closure apparatus of a wireless communication device having a heat-dissipating structure. The closure apparatus comprises: a first housing; and a second housing manufactured to be mechanically separated from the first housing and coupled to the first housing with preset spacing. The second housing includes equipment pre-selected based on the degree of heat dissipation from among multiple pieces of equipment of the communication device. The first housing includes equipment other than the equipment of the second housing.

### CROSS-REFERENCE TO RELATED APPLICATIONS

This application is a continuation of International Application No. PCT/KR2012/006248 filed on Aug. 6, 2012. The application is incorporated herein by reference.

### TECHNICAL FIELD

The present invention relates to a box apparatus for a wireless communication device.

### BACKGROUND ART

As generally known in the art, various pieces of communication equipment are mounted in a box for a wireless communication device such as a base station of a wireless communication system, and include pieces of equipment, such as a radio frequency (RF) signal processing module, a high speed signal processing module, a power supply module, and a digital processing module, which generates a great amount of heat.

Due to the heat generated while the equipment is operated at a maximum load, the temperature of the air in the box for a communication device, which contains the equipment, increases. If the temperature of the air in the box increases, the life span of the equipment is shortened by the heat and the function of the equipment deteriorates, and this also badly influences adjacent pieces of equipment and even causes a malfunction or a data processing error.

Meanwhile, in the base station of the mobile communication system, the base station apparatuses are installed on the ground as compared with antenna apparatuses (generally, having a large volume and a heavy weight) installed at a column located high above the ground and the base station apparatuses are currently connected through cables. However, in recent years, as apparatuses have become lightweight and small-sized, the base station apparatuses are also installed in antenna installation columns at the same locations as that of the antenna apparatuses and a method of directly connecting the base station apparatuses to the antenna apparatuses are being applied.

However, because various pieces of equipment are further densely installed in the base station apparatuses, heat emission and problems due to the heat emission become more important. Moreover, because a temperature rising factor of the box further increases due to waterproofing, moisture-proofing, anti-vibration rigging, and the like of the closing structure, a technology for promptly emitting the heat generated by the box to the outside of the box is required.

A basic technology for increasing heat emission efficiency may include a measure of increasing heat emission areas of heat radiation fins including a plurality of heat radiation fins for the emission of heat. However, size and weight are increased by widening the heat emission area of the heat emission plate. This causes a difficulty in installation costs and installation work in the case of an outdoor communication device installed high above the ground, as well as manufacturing costs.

### SUMMARY

Accordingly, the present invention provides a box apparatus for a wireless communication device having a heat emission structure which enables more efficient heat emission.

The present invention also provides a box apparatus for a wireless communication device which has a smaller size due to a better heat emission efficiency and has a heat emission structure for easily configuration and installation of the box apparatus.

In accordance with an aspect of the present invention, there is provided a box apparatus for a wireless communication device having a heat emitting structure, the box apparatus including: a first housing; and a second housing manufactured to have a structure mechanically separated from the first housing and coupled to the first housing while being spaced apart from the first housing by a preset distance, wherein the second housing is provided with a piece of equipment selected in advance from a plurality of pieces of equipment of the communication device according to a degree of heat emission.

Preferably, the piece of equipment provided in the second housing includes a high power amplification module.

Preferably, a plurality of interval maintenance members are installed to maintain a preset interval between the first housing and the second housing when the first housing and the second housing are coupled to each other.

Preferably, an auxiliary cover having a plurality of windows is installed between the first housing and the second housing to extend from side surface of the first housing and the second housing.

Preferably, the first housing and the second housing are tightly closed to protect the pieces of equipment in the interiors of the first housing and the second housing.

Preferably, signals are connected between the first housing and the second housing using a connector having a jack and a plug, and the plug is tilted with a resiliency.

Preferably, the plug includes: a body substantially having a hollow cylindrical shape, having a large diameter portion having a large diameter at one side thereof and a small diameter portion having a small diameter at an opposite side thereof, and having a coupling portion extending from the large diameter portion such that the jack is coupled to the plug; a central conductor installed in an interior hollow of the body, for transmitting a signal; a fixing plate having a hole at the center thereof, the small diameter portion of the body being inserted through the hole, the diameter of the hole being larger than the diameter of the small diameter portion to have a preset margin and being smaller than the diameter of the large diameter portion, the fixing plate having a fixing hole for coupling to the outside through a fixing means; a fixing pin fixedly inserted through interference-fitting into a distal end of the small diameter portion protruding through the hole of the fixing plate while the small diameter portion of the body is inserted into the hole of the fixing plate and the size of which is set be larger than the diameter of the hole; a spring installed to surround the small diameter portion of the body, and one end of which is supported by a step formed at a border of the large diameter portion and the small diameter portion and an opposite end of which is supported by the fixing plate, for providing a restoring force for restoring the body to an original position when the body is moved; and a hollow housing formed to surround the coupling portion and the large diameter portion of the body, and a portion of the spring.

Preferably, The box apparatus further includes a third housing manufactured to be mechanically separated from the first housing and coupled to the first housing to be spaced from the first housing by a preset distance, wherein the third housing is provided with a piece of equipment selected in advance from a plurality of pieces of equipment of the communication device according to a degree of heat emission, in addition to the piece of equipment provided in the second housing.

Preferably, the second housing and the third housing are located on opposite sides of the first housing with respect to an installation state of the body apparatus.

Preferably, the pieces of equipment provided in the second housing and the third housing include high power amplification modules.

Preferably, the first housing and the second housing, and the first housing and the third housing have through-holes on facing surfaces thereof, protrusions extend from outer surfaces of the first housing on which the holes are formed toward the second housing and the third housing or from outer surfaces of the second housing and the third housing on which the holes are formed toward the first housing, and a signal is connected between the housings by a cable connected through the holes.

Preferably, a plurality of heat radiation fins for heat emission are formed in the second housing and the third housing, and are formed lengthily in the convection direction with respect to the installation state of the box apparatus.

Accordingly, the box apparatus for a wireless communication device having a heat emission structure according to the present invention has excellent heat emission efficiency, can be miniaturized, and can be easily manufactured and installed.

### BRIEF DESCRIPTION OF THE DRAWINGS

FIG. 1 is an exploded perspective view of a box apparatus for a wireless communication device having a heat emission structure according to a first embodiment of the present invention;

FIG. 2 is a front view showing a coupled state of FIG. 1;

FIG. 3 is a cutaway sectional view taken along line A-A′ of FIG. 1;

FIG. 4 is a perspective view of a plug and a jack of a connector of FIG. 1;

FIG. 5 is an exploded perspective view of the plug of FIG. 4;

FIG. 6 is a sectional view of the plug of FIG. 4, which is taken along line A-A;

FIG. 7 is a view showing an in-use state of the plug shown in FIGS. 4 to 6;

FIG. 8 is an exploded perspective view of a box apparatus for a wireless communication device having a heat emission structure according to a second embodiment of the present invention; and

FIG. 9 is a cutaway sectional view taken along line A-A′ of FIG. 8.

### DETAILED DESCRIPTION

Hereinafter, exemplary embodiments of the present invention will be described in detail with reference to the accompanying drawings.

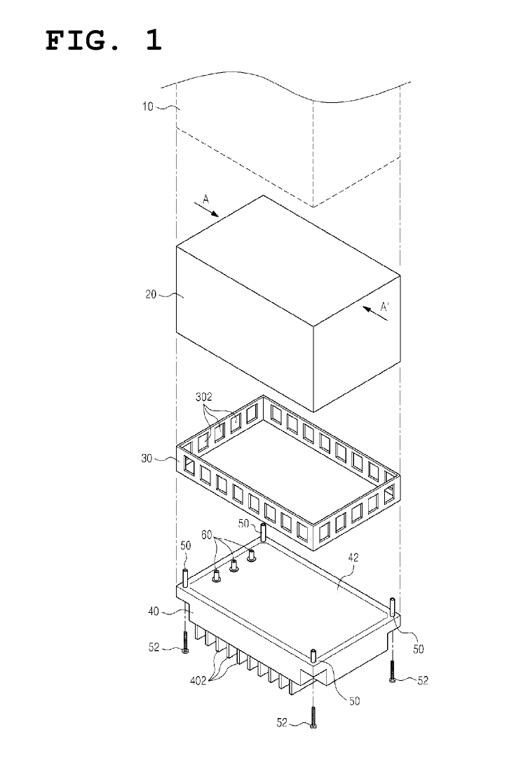

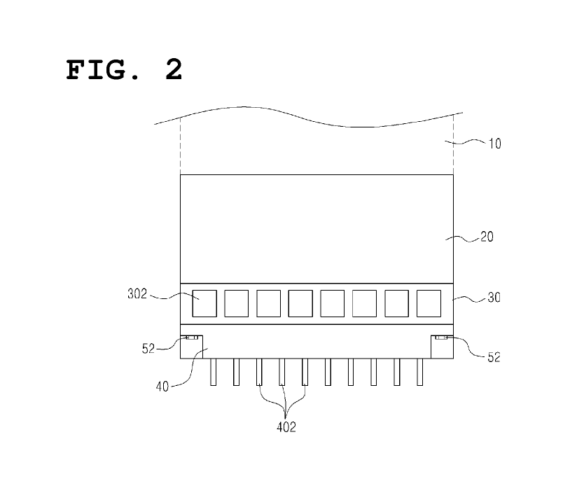

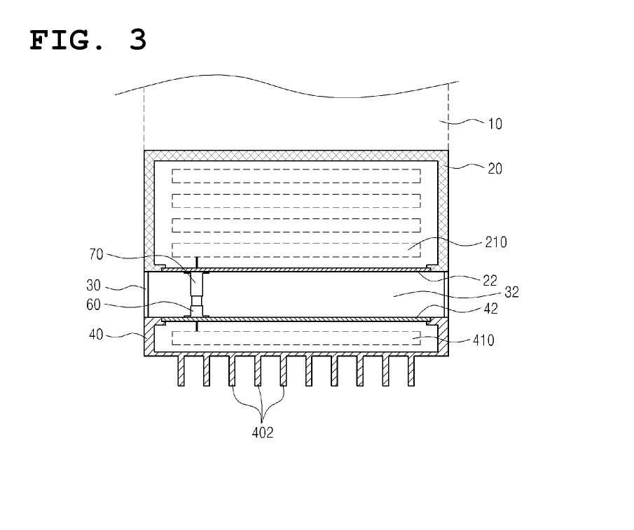

FIG. 1 is an exploded perspective view of a box apparatus for a wireless communication device having a heat emission structure according to a first embodiment of the present invention. FIG. 2 is a front view showing a coupled state of FIG. 1. FIG. 3 is a cutaway sectional view taken along line A-A′ of FIG. 1.

Referring to FIGS. 1 to 3, the box apparatus for a wireless communication device according to the first embodiment of the present invention includes: a first housing 20; a second housing 40 manufactured to have a structure mechanically separated from the first housing 20 and coupled to the first housing 20 while being spaced apart from the first housing 20 by a preset distance.

The first housing 20 is provided with the most pieces of equipment of the wireless communication device, such as a radio frequency (RF) signal processing module, a high speed signal processing module, a power supply module, and a digital processing module, for example, when the corresponding wireless communication device is a base station apparatus, and the second housing 40 is provided with a preselected piece of equipment, for example, a high power amplification module, which generates a large amount of heat among several pieces of equipment of the corresponding wireless communication device.

A plurality of interval maintenance members 50 inserted between the first housing 20 and the second housing 40 when the first housing 20 and the second housing 40 are coupled to each other to maintain a preset distance between the first housing 20 and the second housing 40. The first housing 20 and the second housing 40 may be coupled to each other by a plurality of screws 52, and holes for the screws 52 are formed in the plurality of interval maintenance members 50. The plurality of screws 52 are coupled to holes formed in the second housing 40 at a lower side (in the drawings) of the second housing 40 and screw holes formed at locations corresponding to the holes of the first housing 20 through the holes formed in the interval maintenance member 50 to fixedly attach the first housing 20 and the second housing 40.

In this way, because the first housing 20 and the second housing 40 are coupled to each other to be spaced apart from each other at a preset distance, an air layer 32 is formed between the first housing 20 and the second housing 40. An auxiliary cover 30 is further installed at an outer edge of the air layer 32, that is, in a shape extending in a mutual direction from the first housing 20 and the second housing 40 to provide an appealing external appearance and an additional support force. The auxiliary cover 30 may be formed of a material which does not allow easy heat transfer, for example, a plastic material. Ventilation or convection for emission of heat may be smoothly made by a window 302 of the auxiliary cover 30.

As described above, the communication device according to the present invention, to which the first housing 20 and the second housing 40 are coupled, may be then directly or indirectly attached to an antenna apparatus 10 or may be attached for antenna installation column using a separate bracket apparatus.

It can be seen that the above-configured box apparatus for a communication device according to the first embodiment of the present invention individually separates only pieces of equipment which generate the most heat among several pieces of equipment of the corresponding communication device and installs them in the second housing 40, which is a separate housing.

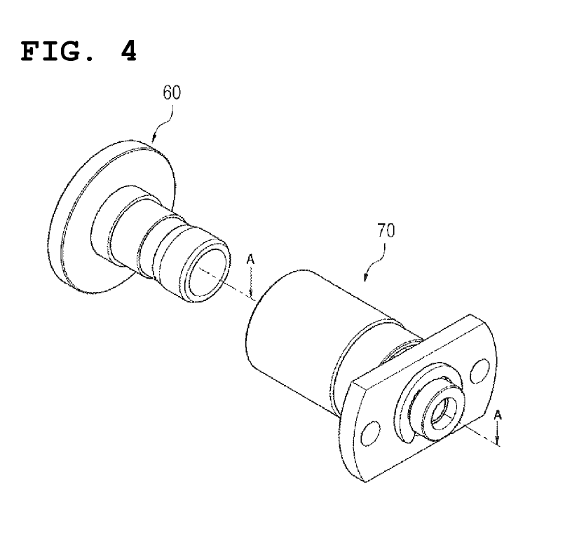

For example, when the corresponding communication device is a base station apparatus, in particular, as shown in FIG. 4, the first housing 20 and the second housing 40 are separately manufactured in a manner the second housing 40 is tightly closed by a second housing cover 42 after a substrate 410 of a high power amplification module is installed within the second housing 40 and the first housing 20 is tightly closed by a first housing cover 22 after substrates 210 of the other pieces of equipment are installed within the first housing 20. In the base station apparatus, heat corresponding to about ⅔ of an entire heating value may be generated even only the substrate 410 of the high power amplification module.

Accordingly, the present invention can intensively apply a heat emission structure to equipment having high heat emission together with a plurality of heat radiation fins 402 for heat emission formed outside the second housing 20, thereby improving heat emission efficiency. Moreover, because the first housing 20 and the second housing 40 are separately formed and coupled to be spaced apart from each other such that the air layer is formed between the first housing 20 and the second housing 40, heat generated from the heat emitting equipment provided in the second housing 40 does not influence the first housing 20. Accordingly, heat does not badly influence several pieces of equipment provided in the first housing 20.

Meanwhile, a signal connection method of the first housing 20 and the second housing 40 may employ a general method using a cable and a connector, but an improved snap-on type connector is used in the first embodiment of the present invention.

In general, the connector may be classified into a coupling nut type and a snap-on type according to a coupling method, and a coupling nut type connector has a structure in which a plug having an outer peripheral surface on which a nut is mounted and a jack having a male screw on an outer peripheral surface thereof, such that the male screw is coupled to the nut are screw-coupled to each other. The snap-on type connector has a structure in which a boss formed at one end of a body of a plug and a recess formed in an interior of a body of a jack and into which a boss may be inserted are coupled to each other in an insertion method.

Then, in the case of the snap-on method, because a plug and a jack are simply coupled to each other through an insertion method, they may be promptly coupled to each other.

As shown in FIGS. 1 to 3, the first housing 20 and the second housing 40 may be connected to each other for connection of signals using a snap-on type connector, and for example, a plurality of plugs 70 may be provided in the first housing 20 and a plurality of jacks 60 may be provided in the second housing 40 at locations corresponding to the plugs 70.

Because the plurality of plugs 70 and the plurality of jacks 60 are fitted with each other when the first housing 20 and the second housing 40 are fixed to each other, the plurality of plugs 70 and the jacks 60 are connected to each other.

However, when the plugs 70 and the jacks 60 are misaligned due to the manufacturing tolerances of the plugs 70 and the jacks 60, they may not be normally coupled to each other. Moreover, when a plurality of connectors are arranged, the problem may become severe.

Accordingly, the first embodiment of the present invention provides a snap-on type connector having an improved structure such that the plugs 70 and the jacks 60 may be normally engaged with each other while some manufacturing tolerances are allowed.

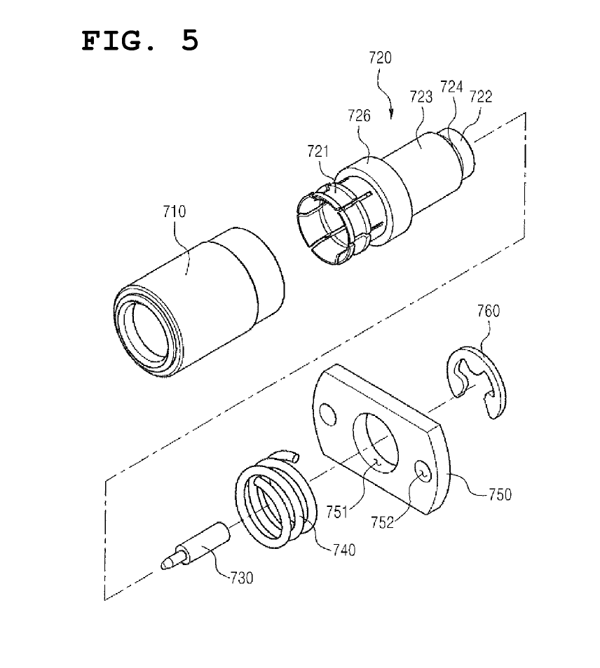

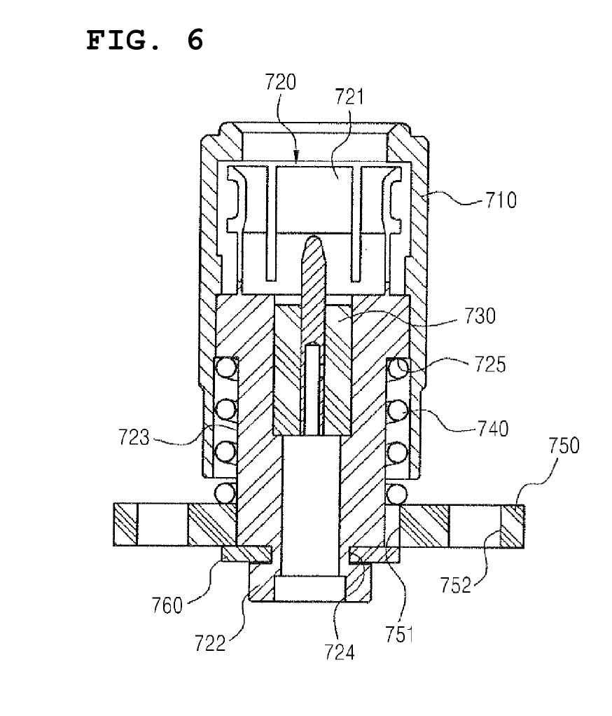

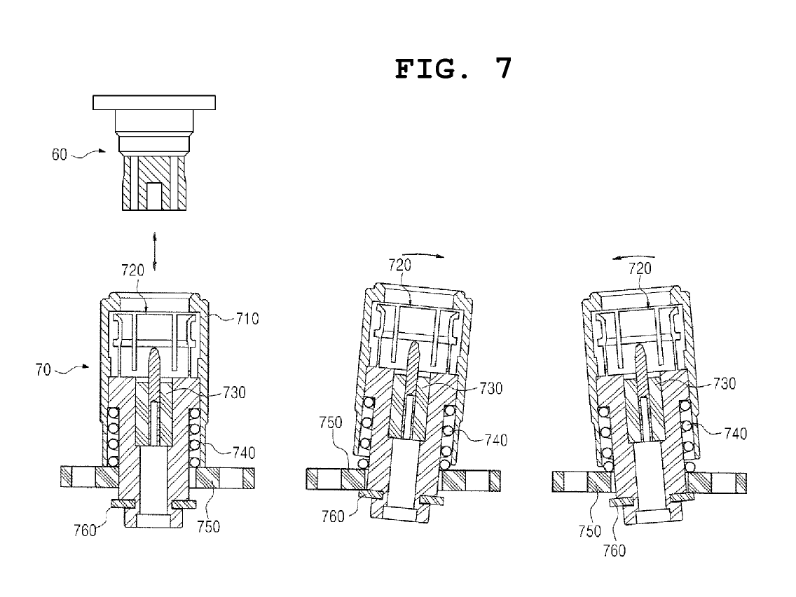

FIG. 4 is a perspective view of the plug 70 and the jack 60 of the snap-on type connector of FIG. 1. FIG. 5 is an exploded perspective view of the plug 70 of FIG. 4. FIG. 6 is a sectional view of the plug 70 of FIG. 4, which is taken along line A-A. FIG. 7 is a view showing an in-use state of the plug 70 shown in FIGS. 4 to 6.

Referring to FIGS. 4 to 7, the connector according to the first embodiment of the present invention includes a jack 60 acting as a bolt, and a plug 70 accommodating the jack 60 therein.

The plug 70 has a substantially hollow cylindrical shape, and has a body 720 having a large diameter portion 726 of a large diameter at one side thereof and having small diameter portions 722 and 723 of small diameters at an opposite side thereof. Then, the small diameter portions 722 and 723 may be classified into a first small diameter portion 723 and a second small diameter portion 722 in an extension direction of the large diameter portion 726, and then the second small diameter portion 722 may have the smallest diameter.

The body 720 has a coupling portion 721 extending from the large diameter portion 726 and to which the jack 60 will be coupled, and a central conductor 730 for transmitting a signal is installed in an interior hollow of the body 720.

The body 720 is fixed by a fixing plate 750, a fixing pin 760, and a spring 740, and first, the fixing plate 750 has a plate shape having a hole 752 at the center thereof and the small diameter portions 722 and 723 of the body 720 are inserted into the hole 750 to pass through the hole 752. Then, the diameter of the hole 752 is large enough to have a preset margin as compared with the diameters of the small diameter portions 722 and 723, and is smaller than the diameter of the large diameter portion 726.

A plurality of fixing holes 752 into which fixing means (not shown) such as screws are inserted to be coupled to the fixing holes 752 are formed in the fixing plate 750 such that the fixing plate 750 is fixed to an external substrate or the like.

In the state in which the small diameter portions 722 and the 723 of the body 720 are inserted into the hole 752 of the fixing plate 750, the fixing pin 760 is fixedly interference-fitted with the small diameter portions 722 and 723 protruding through the hole 752 of the fixing plate 750, that is, with the second small diameter portion 722 with a structure formed in advance to be engaged with the fixing pin 760, in which case the size of the fixing pin 760 is set to be larger than the diameter of the hole 752 such that the small diameter portions 722 and 723 from being separated from the hole 752.

The first diameter portion 723 of the body 720 is installed to be surrounded by the cylindrical spring 740, and provides a restoring force for restoring the body 720 to an original position when one end of the spring 740 is supported by a step 725 formed at a border of the large diameter portion 726 and the first small diameter portion 723 and an opposite end of the spring 740 is supported by the fixing plate 750 such that the body 720 is moved, that is, when the body 720 is moved forwards and rearwards (vertically in the drawing) and is inclined upwards, downwards, leftwards, and rightwards (horizontally in the drawing).

A hollow housing 10 formed to surround the coupling portion 721, the large diameter portion 726, and a portion of the cylindrical spring 740 of the body 720 may be installed in the body 720, for example, interference-fitted with the body 720.

In this state, the small diameter portions 722 and 723 of the body 720 of the plug 70 are located in the hole 751 of the fixing plate 750, in which case because the outer diameters of the small diameter portions 722 and 723 are smaller than the inner diameter of the hole 751 of the fixing plate 750, the body 720 may move forwards, rearwards, upwards, downwards, leftwards, and rightwards from the fixing plate 750 to a degree as shown in FIG. 4.

In this way, because the body 720 may be moved forwards and rearwards and inclined upwards, downwards, leftwards, and rightwards to a degree while the plug 70 of the connector is fixed to the substrate, the cover or the like, the plug 70 and the jack 60 may be smoothly connected to each other even though the jack 60 fitted with the plug 70 is installed at a location having some errors.

Due to the connector, the box apparatus according to the embodiment of the present invention may have an integral external appearance. As described above, the box apparatus according to the embodiment of the present invention separately includes a first box and a second box, but the first box and the second box are electrically connected to each other and an auxiliary cover is provided between the first box and the second box so that an external appearance of the box apparatus may seem to be integral.

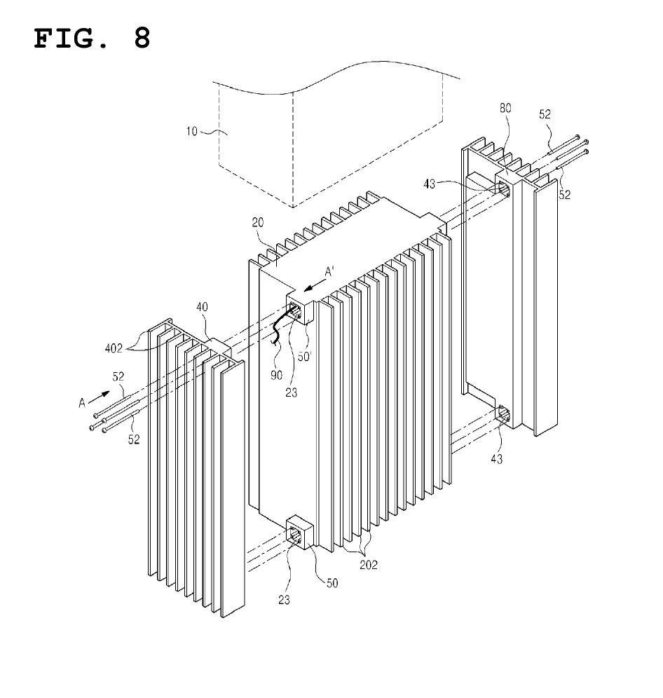

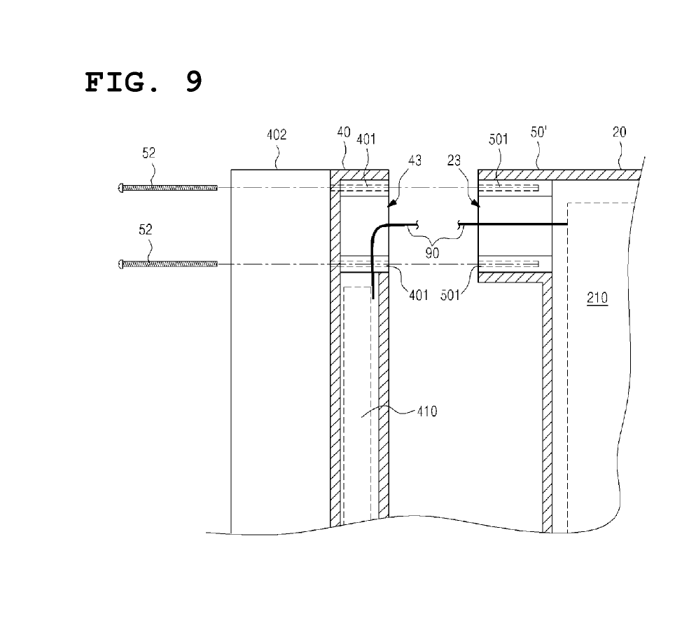

FIG. 8 is an exploded perspective view of a box apparatus for a wireless communication device having a heat emission structure according to a second embodiment of the present invention. FIG. 9 is a cutaway sectional view taken along line A-A′ of FIG. 8. The second embodiment of the present invention shown in FIGS. 8 and 9 has a structure similar to that of the first embodiment of the present invention shown in FIGS. 1 to 3, and the constituent elements for performing similar functions are given the same reference numerals.

Referring to FIGS. 8 to 9, similarly to the configuration of the first embodiment shown in FIGS. 1 to 3, the box apparatus for a wireless communication device according to the second embodiment of the present invention includes: a first housing 20; a second housing 40 manufactured to have a structure mechanically separated from the first housing 20 and coupled to the first housing 20 while being spaced apart from the first housing 20 by a preset distance. Meanwhile, in addition to the configuration, the second embodiment of the present invention further includes a third housing 80 manufactured to have a structure mechanically separated from the first housing 20 and coupled to the first housing 20 while being spaced apart from the first housing 20 by a preset distance like the second housing 40.

That is, in the second embodiment of the present invention, the second housing 40 and the third housing 80 are located on the left and right side surfaces of the first housing 30, that is, opposite sides of the first housing 30 with respect to the installation state of the box apparatus, that is, with respect to the installation location of the antenna apparatus 10, so as to be coupled to each other.

The first housing 20 is provided with most pieces of equipment of the wireless communication device, such as a radio frequency (RF) signal processing module, a high speed signal processing module, a power supply module, and a digital processing module, for example, when the corresponding wireless communication device is a base station apparatus, and the second housing 40 and the third housing 80 are provided with a preselected piece of equipment, for example, a high power amplification module, which generates a large amount of heat among several pieces of equipment of the corresponding wireless communication device.

That is, the high power amplification module may include a plurality of high power amplification elements, and some elements may be provided in the second housing 40, and the remaining ones may be provided in the third housing 80. The second housing 40 may include equipment selected because it generates heat most, and the third housing 80 may include equipment selected because it generates heat the second most.

It can be seen that as compared with the first embodiment of the present invention, in the box apparatus for a communication device according to the second embodiment of the present invention, several pieces of equipment are distributed in the second housing 20 and the third housing 80, so that heat emission efficiency can be further increased.

Meanwhile, one or more holes 23 are formed on surfaces of the first housing facing the second housing 40 and the third housing 80, and protrusions 50′ protruding and extending toward the second and third housings 40 and 80 are provided around the holes 23. That is, the first housing 20 and the second and third housings 40 and 80 may be spaced apart from each other by a predetermined distance due to the protrusions 50′, and heat may be radiated through the spaces through convection.

Although it has been exemplified in the embodiment of the present invention that the protrusions 50′ are integrally formed with the first housing 20, a separate tubular member may be attached or screw-coupled to the first housing 20.

Ends of the tubular protrusions 50′ facing the first and second housings 40 and 80 have screw recesses 501 to which a plurality of screws 52 may be coupled, and through-holes 401 through which the screws 52 may pass are formed in the second housing 40 and the third housing 80. The plurality of screws 52 are coupled to the screw recesses 501 formed in the interval maintenance members 50 on outer surfaces of the second housing 40 and the third housing 80 through the through-holes formed in the second housing 40 and the third housing 80, so that the first housing 20 and the second housing 40, and the first housing 20 and the third housing 80 may be fixedly attached to each other.

Then, although signal connection schemes between the first housing 20 and the second housing 40, and the first housing 20 and the third housing 80 may employ a method of using a snap-on type connector according to the first embodiment of the present invention shown in FIGS. 1 to 7, a method of using a general cable 90 is used in the second embodiment of the present invention. That is, interior spaces of the tubular protrusions 50′ are used as passages for a cable. One end of the cable 90 is connected to a substrate 210 of the internal equipment of the first housing 20 through the interior space of the tubular protrusion 50′ and an opposite end of the cable 90 is connected to a substrate 410 of the internal equipment of the second housing 40 (or the third housing), so that a signal is connected between (the pieces of internal equipment of) the separated housings with a simpler structure. Of course, holes 43 through which the cable 90 passes are formed at locations of the second housing 40 and the third housing 80 corresponding to the interior spaces of the tubular protrusions 50′, and the other parts are tightly closed.

Meanwhile, in the second embodiment of the present invention, a plurality of heat radiation fins 402 for heat emission are formed in the second housing 40 and the third housing 80 and a plurality of heat radiation fins 202 are formed in the first housing 20, and because the heat radiation fins 402 and 202 are formed lengthily with respect to the installation state of the box apparatus, heat radiation efficiency can be increased by smoothly circulating air through convection.

The box apparatus for a wireless communication device having the heat emission structures according to the embodiments of the present invention may be configured in this way, and the detailed embodiments of the present invention have been described, various modifications can be made without departing from the scope of the present invention.

For example, although it has been described in the first embodiment shown in FIGS. 1 to 3 that an auxiliary cover 30 is installed between the first housing 20 and the second housing 30, the auxiliary cover 30 may not be provided according to occasions and the form and material of the auxiliary cover 30 may be variously designed.

Further, in the first embodiment of the present invention shown in FIGS. 1 to 3, a plurality of heat radiation fins 402 for heat emission are formed in the second housing 40 but a plurality of heat radiation fins also may be provided in the first housing 20.

When the box apparatus for a communication device according to the present invention in which the first housing 20 and the second housing 40 are coupled to each other is coupled to the antenna apparatus 10, the connector structure for transmission of signals may employ the snap-on type connector according to the first embodiment of the present invention shown in FIGS. 4 to 7.

In the first embodiment of the present invention shown in FIGS. 4 to 7, the fixing pin 760 of the connector has an E shape in which a disk plate shape is partially removed from the center to an outer peripheral surface thereof, and the partially removed and opened portion is fixedly inserted into the second small diameter portion 722 of the body 720 through interference-fitting, and the second small diameter portion 722 has a structure having a positioning recess 724 in which the fixing pin 760 is inserted and positioned.

However, in addition to the configuration, the fixing pin 760 may simply have a clip or bar shape, and the second small diameter portion 722 may have a recess or hole into which the fixing pin 760 is inserted.

Although it has been described in the second embodiment of the present invention shown in FIGS. 8 and 9 that the second housing 40 and the third housing 80 are installed on the left and right side surfaces of the first housing 20, any one of the second housing 40 and the third housing 80 may be installed on a front surface or a rear surface of the first housing 20 to occupy a partial range or an entire range thereof. In addition, one or more separate housings may be further provided together with the second housing 40 and the third housing 80 to be installed on a front surface, a rear surface, or a bottom surface of the first housing 20.

Although it has been described in the second embodiment of the present invention shown in FIGS. 8 and 9 that the tubular protrusions 50′ are integrally fixed to the first housing 20, the tubular protrusions may be integrally fixed to the second housing 40 and the third housing 80. In this case, through-holes through which screws pass through may be formed in the tubular interval maintenance members, and screw recesses to which screws are coupled may be formed at corresponding locations of the first housing.

1. A box apparatus for a wireless communication device having a heat emitting structure, the box apparatus comprising:
a first housing; and
a second housing manufactured to have a structure mechanically separated from the first housing and coupled to the first housing while being spaced apart from the first housing by a preset distance,
wherein the second housing is provided with a piece of equipment selected in advance from a plurality of pieces of equipment of the communication device according to a degree of heat emission.

2. The box apparatus of claim 1, wherein the piece of equipment provided in the second housing comprises a high power amplification module.

3. The box apparatus of claim 1, wherein a plurality of interval maintenance members are installed to maintain a preset interval between the first housing and the second housing when the first housing and the second housing are coupled to each other.

4. The box apparatus of claim 1, wherein an auxiliary cover having a plurality of windows is installed between the first housing and the second housing to extend from side surface of the first housing and the second housing.

5. The box apparatus of claim 1, wherein the first housing and the second housing are tightly closed to protect the pieces of equipment in the interiors of the first housing and the second housing.

6. The box apparatus of claim 1, wherein signals are connected between the first housing and the second housing using a connector having a jack and a plug, and the plug is tilted with a resiliency.

7. The box apparatus of claim 6, wherein the plug comprises:
a body substantially having a hollow cylindrical shape, having a large diameter portion having a large diameter at one side thereof and a small diameter portion having a small diameter at an opposite side thereof, and having a coupling portion extending from the large diameter portion such that the jack is coupled to the plug;
a central conductor installed in an interior hollow of the body, for transmitting a signal;
a fixing plate having a hole at the center thereof, the small diameter portion of the body being inserted through the hole, the diameter of the hole being larger than the diameter of the small diameter portion to have a preset margin and being smaller than the diameter of the large diameter portion, the fixing plate having a fixing hole for coupling to the outside through a fixing means;
a fixing pin fixedly inserted through interference-fitting into a distal end of the small diameter portion protruding through the hole of the fixing plate while the small diameter portion of the body is inserted into the hole of the fixing plate and the size of which is set be larger than the diameter of the hole;
a spring installed to surround the small diameter portion of the body, and one end of which is supported by a step formed at a border of the large diameter portion and the small diameter portion and an opposite end of which is supported by the fixing plate, for providing a restoring force for restoring the body to an original position when the body is moved; and
a hollow housing formed to surround the coupling portion and the large diameter portion of the body, and a portion of the spring.

8. The box apparatus of claim 1, further comprising a third housing manufactured to be mechanically separated from the first housing and coupled to the first housing to be spaced from the first housing by a preset distance, wherein the third housing is provided with a piece of equipment selected in advance from a plurality of pieces of equipment of the communication device according to a degree of heat emission, in addition to the piece of equipment provided in the second housing.

9. The box apparatus of claim 8, wherein the second housing and the third housing are located on opposite sides of the first housing with respect to an installation state of the body apparatus.

10. The box apparatus of claim 8, wherein the pieces of equipment provided in the second housing and the third housing comprise high power amplification modules.

11. The box apparatus of claim 8, wherein the first housing and the second housing, and the first housing and the third housing are spaced apart from each other by a predetermined distance and heat is radiated from the spaces through convection.

12. The box apparatus of claim 11, wherein the first housing and the second housing, and the first housing and the third housing have through-holes on facing surfaces thereof, protrusions extend from outer surfaces of the first housing on which the holes are formed toward the second housing and the third housing or from outer surfaces of the second housing and the third housing on which the holes are formed toward the first housing, and a signal is connected between the housings by a cable connected through the holes.

13. The box apparatus of claim 8, wherein a plurality of heat radiation fins for heat emission are formed in the second housing and the third housing, and are formed lengthily in the convection direction with respect to the installation state of the box apparatus.
